(19) United States
(12) Patent Application Publication
(10) Pub. No.: US 2010/0138723 A1
(43) Pub. Date: Jun. 3, 2010

(54) METHOD AND APPARATUS FOR CORRECTING DATA ERRORS AND METHOD AND APPRATUS FOR PLAYING BACK A DISC

(75) Inventors: Jin Wang, Shanghai (CN); Daqing Zhang, Shanghai (CN)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/916,562

(22) PCT Filed: May 31, 2006
(86) PCT No.: PCT/IB2006/051725

§ 371 Date: Dec. 5, 2007

(30) Foreign Application Priority Data
Jun. 9, 2005 (CN) 200510077843.2

(51) Int. Cl. H03M 13/05; G06F 11/10

(52) U.S. Cl. 714/769; 714/E11.034

(57) ABSTRACT

The present invention provides an error correction method and apparatus, and also an optical disc playback method and apparatus. The error correction method in the present invention is used to perform error correction on data read from an optical disc, comprising: obtaining the error detection information of a block corresponding to the read data; determining data error type in a data stream unit derived from the block according the error detection information; according to the data error type and predefined reference error type, judging whether to reserve the data stream unit for optical disc playback. By using the error detection information of the block which is decarded by using the existing technologies, the player can perform further error correction to try to avoid data errors which may produce interruption during optical disc playback.

### FIELD OF THE INVENTION

The present invention relates generally to the field of optical storage technology, and more particularly, to a method and apparatus for correcting data errors, and also to a method and apparatus for playing back a disc.

### BACKGROUND OF THE INVENTION

In the field of optical storage technology, different physical formats and logical formats of optical discs are evolving with diverse functionalities. Tremendous capacity of optical storage, flexible user interface, powerful network linkage function and fluent and vivid playback effect, have already featured significantly in the development of optical storage.

With the rapid development of optical storage technology, the demands for exquisite optical storage are rising, one of which is to correct data errors to improve playback effect. During the playback, it is almost inevitable to occur errors during reading data, meanwhile, due to the difference between the research/development and manufacturing level of different suppliers, and also misuse of optical discs and equipments, the possibility of error happening receives considerable increase.

There are many technical solutions for error correction when reading data from an optical disc in the prior art. For instance, in DVD (digital versatile disc) players, front end performs Reed-Solomon Code (RS) correction for ECC (error correction code) block read from the optical disc. RS correction is able to detect and fix the data errors of some particular types, nevertheless, for other types of errors, it can only detect but is not capable to correct them. If the amount of detected while not possible to be corrected errors exceeds a set threshold, the ECC block will be marked as “BAD” before discarded, and no subsequent data processing is performed on such block; otherwise, the ECC block will be marked as “OK” before it is transmitted to the player's back end. Such error correction method effectively eliminates the impact of blocks with severe errors on optical disc's playback. However, this method can only apply for finite error correction for ECC block and can not be used for detecting and correcting errors of data in data stream, and also, it can not implement fine error correction for data at lower-level layer.

The block transmitted to the back end is separated into packs (e.g. navigation pack, video pack and audio pack, etc.,) in form of data-stream by demultiplexer, and then it undergoes data processing such as decoding and the like before being used for playback.

During the decoding processing on video packs, the back end of player performs error correction beneath the lower data layer (namely macro slice data layer). If key data beneath the macro slice data layer encounter uncorrectable severe errors, the decoding processing can not continue, which results in interrupting the playback. In addition, the amount of errors occurring beneath macro slice data layer may be not too much, but they may comparatively concentrate in given data sectors, which make the sector unusable, as consequence, the playback will also be interrupted. In a navigation pack, a key guiding address error may also cause that relating information can not be found and then the decoding processing can not be proceeded.

Therefore, a method and apparatus for error correction, and also a method and apparatus for optical disc's playback are needed to improve the capability of error correction and the effect of the playback.

### SUMMARY OF THE INVENTION

The object of the present invention is to provide a method and apparatus for error correction, and also a method and apparatus for optical disc playback to overcome the current deficiencies in prior art.

According to an embodiment of the present invention, a method for error correction is provided to perform error correction for data read from an optical disc. The method comprises steps of: obtaining error detection information of a block corresponding to the read data; according the detection information, determining data error type in one data stream unit derived from the block; according to the data error type and predefined referenced error type, judging whether to reserve the data stream unit for optical disc playback. The error correction method can further comprise the step: if the data stream unit is not reserved, instructing to discard the data used for the playback, which is referring to the data stream unit.

According to an embodiment of the present invention, it provides an apparatus for error correction to perform error correction on data read from a optical disc, comprising: an obtaining apparatus for obtaining error detection information of a block from the read data; a determining means, for determining data error type in one data stream unit derived from the block according to the error detection information; a judging means, for judging whether to reserve the data stream unit for optical disc playback according to the data error type and predefined reference error type. The error correction apparatus further contains a instructing means, for instructing to discard the data of the data stream unit for playback if the data stream unit is not reserved.

According to an embodiment of the present invention, it provides a method for optical disc playback, comprising steps: performing error correction for data read from an optical disc to generate error detection information of a block corresponding to the read data; obtaining the error detection information; according to the error detection information, determining data error type in one data stream unit derived from the block; judging whether to reserve the data stream unit for optical disc playback according to the data error type and predefined referenced error type.

According to an embodiment of the present invention, it provides an apparatus for optical disc playback, comprising: a detecting means for performing error detection on data read from an optical disc to generate error detection information of a block corresponding to the read data; a obtaining means for obtaining the error detection information; a determining means, according to the error detection information, for determining data error type in one data stream unit derived from the block; a judging means, for judging whether to reserve the data stream unit for optical disc playback according to the data error type and predefined referenced error type.

By recycling the error detection information of the block (e.g. ECC block) discarded by the front end of an optical disc player in prior art, performing further error type judgment for different data stream units at the back end, and making further decisions whether to discard the data stream unit and relating data or not, the present invention not only improves the accuracy of error correction, but also effectively avoids the undesired events hindering optical disc's normal playback during decoding process.

Other objects and attainments together with a fuller understanding of the invention will become apparent and appreciated by referring to the following description and claims taken in conjunction with the accompanying drawings.

### BRIEF DESCRIPTION OF THE DRAWINGS

Detailed description will be given below to the present invention in conjunction with specific embodiments and accompanying drawings, in which:

FIG. 1 is a flowchart illustrating an error correction method according to an embodiment of present invention;

FIG. 2 is a flowchart illustrating an optical disc playback method according to an embodiment of present invention;

FIG. 3 is a block diagram illustrating an error correction apparatus according to an embodiment of the present invention;

FIG. 4 is a schematic diagram illustrating obtained error detection information corresponding to one ECC block according to an embodiment of the present invention; and

FIG. 5 is a schematic diagram illustrating the determined error type of data according to an embodiment of the present invention.

Throughout the drawings, like reference numerals will be understood to refer to like parts and components.

### DETAILED DESCRIPTION OF THE INVENTION

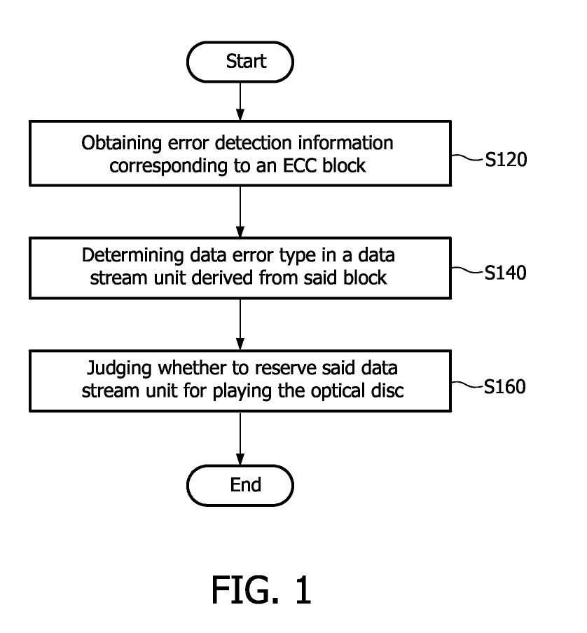

FIG. 1 is a flowchart illustrating an error correction method according to an embodiment of the present invention. Next, the error correction performed on the data read from a DVD will be taken as an example to describe FIG. 1. Firstly, the error detection information of ECC blocks read from a DVD is obtained (step 120). According to the prior art, the front end of DVD player performs error correction in unit of ECC block according to RS correction method, and the yielded error detection information is used for judging if the corresponding ECC block is “BAD” or “OK”, for determining whether to discard this block or not, and then, corresponding error detection information will be discarded. In the present invention, the error detection information of an ECC block being determined as “OK” will be reserved.

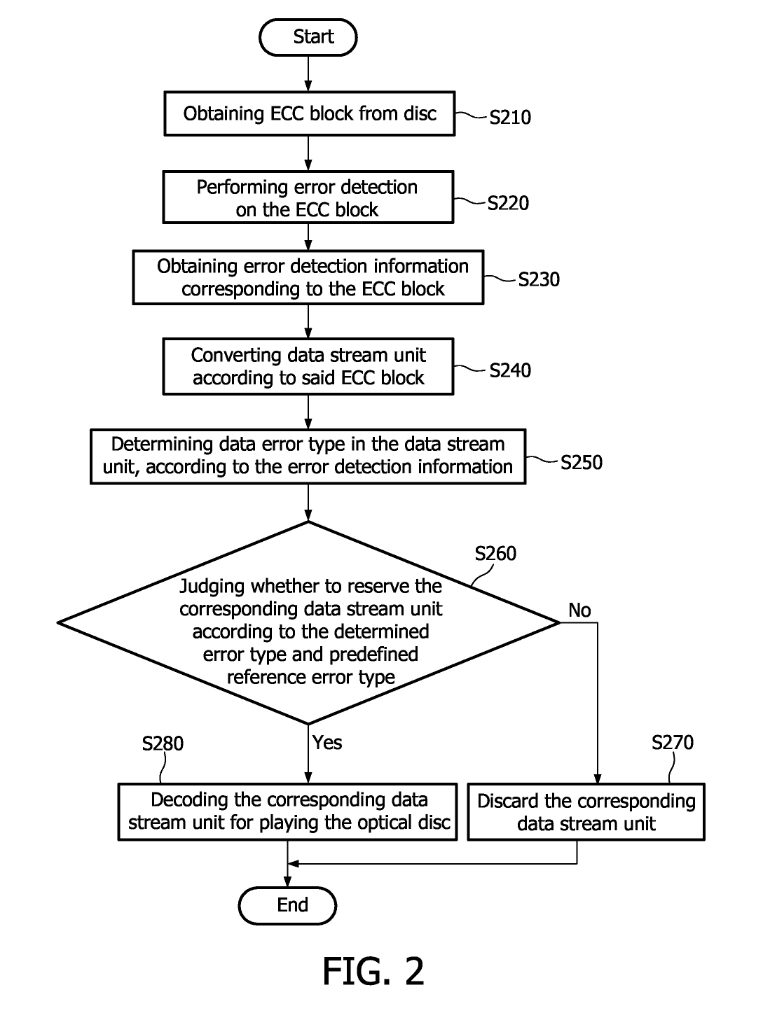

Then, the type of data errors in a data stream unit derived from the block is determined according to the error detection information (step S140). The ECC block transmitted to the back end will be transformed into data stream units. In the form of data stream, the address information of data with errors could be determined according to the error detection information. In a data stream unit, the role of the data stored in specific address in the data stream unit is to judge the impact of the error on the data stream. If the role of the data stored in specific address is indispensable, irreplaceable or not neglectable for the data stream, the data error will cause the data stream unit unusable, otherwise it will cause interruption during playback. Concrete examples can be referred to the description on FIG. 2 below.

Finally, according to the determined data error type and predefined reference type, judging whether to reserve the data stream unit for playback (step S160). The determined data error type could be uncorrectable errors occurred at the address where important or key information should be stored in data stream unit, or a large amount of uncorrectable errors concentratively occurred in some given data sectors, or errors occurred on some inessential data, etc.

The predefined reference error type can be one or one group of data error types, which is used as a criteria for judging whether a data stream unit should be discarded or not. For example, an assumption could be made that if a determined error type belongs to the predefined error types, the data stream unit will be discarded without further data processing or DVD playback.

By comparing the determined error type and predefined reference error type, it is able to be judged whether the corresponding data stream unit can be used for DVD playback or not. If not, the data stream unit needs to be discarded according to known method in the art; otherwise, the data stream unit can be further preceded for DVD playback.

Above error correction method applies the detection information obtained from the front end of player to the judgment of data stream unit's error type at the back end, and further performs error correction on data read from optical disc, which effectively improves accuracy of error correction and playback effect.

FIG. 2 is a flowchart illustrating a playback method of an optical disc according to an embodiment of the present invention. The embodiment takes a DVD playback as an example. Firstly, DVD player reads data from disc (step S210), which is the ECC block read from DVD's data sector. One ECC block contains user data, PI (Parity of Inner code) and PO (Parity of Outer-code), etc.

Then, the front end of the player performs error detection and correction on ECC block (Step S220). The verification of PI and PO is the main approach of error correction during the procedure of reading DVD, which is specified in DVD standard (e.g. DVD+R/RW) in detail. During verification process of PI and PO, the amount of detected errors and their levels are used to judge whether the ECC block can be transmitted to back end of DVD's player or not. The error information obtained through the verification of PI and PO includes the address information of the data with errors.

Subsequently, the player obtains the error detection information of the ECC block (step S230). According to the specification of DVD reading, if the errors detected in PI and PO during the ECC verification process fall in the acceptable range, the ECC block will be transmitted to the back end for further processing, otherwise the ECC block will be discarded without further processing, nor for DVD playback.

In the present invention, the reserved error detection information of the ECC block will be collected and reserved by DVD player while not be discarded as it is done in the prior art. DVD player transmits the obtained error detection information to the back end in various ways, for example, attaching the detection information to corresponding ECC blocks, or transmitting to back end as one file or segments of one file separately.

Subsequently, descrambling and other processing is performed for the ECC block, as a result the ECC block is converted into different kinds of data streams (step S240). During the transmission of the ECC block from front end to back end in the player, the ECC block will be converted into all kinds of data streams, e.g. navigation pack, video pack, audio pack, etc.

And then, according to the obtained error detection information, DVD player determines the data error type in the data stream unit (step S250). Since the data in data stream comes from ECC block, and the error detection information corresponds to the block, the detection information can be therefore used to determine the type of data errors in the data stream unit.

For example, for navigation pack, according to optical disc's standard, it belongs to encoded data with fixed length, and specific addresses are used for saving specific data, e.g. system header and navigation pack header are saved in specific address correspondingly. Therefore, by determining the address of errors, the erroneous data can be determined accordingly. If an error occurs in a data at specific address and the data is irreplaceable for the realization of navigation function, the error will be unacceptable.

Another example is in video data stream, if unacceptable errors occur in one I frame picture, not only the I frame picture can not be used, but the picture data of the B frame and P frame referring to the I frame will also be no use.

Another case is that the amount of errors in a data stream unit or at one certain data sector in the data stream unit exceeds an acceptable threshold. The scenario where the kind of error concentratively occurs in a certain data sector will hinder the subsequent data processing, making it extremely liable to interruption during data processing of player system, therefore, this scenario should be tried to avoid.

According to the determined data error type and predefined reference error type, a judgment is to be made whether to reserve the corresponding data stream unit or not for DVD playback (Step S260). Predefined error type can be determined by vendors according to optical disc's standard and functionality of player system, which could be one or one group of error types description, and it is the criteria to decide whether one data stream unit will be discarded or not.

If the data error type matches the predefined error type, DVD player discards the data stream unit (step S270). If one predefined reference error type occurs in a navigation pack, the navigation pack will be discarded to avoid system crash during subsequent playback. If one I frame in a video pack encounters an unacceptable error, the I frame picture will be discarded, and the picture of B frame or P frame referring to the I frame will also be discarded, accordingly, the whole group of pictures (GOP) containing the I frame will be discarded as well.

If one navigation pack is discarded, the data navigated by the navigation pack, which is still undergoing processing, will also be discarded without further processing. It saves subsequent processing procedure and avoids playback interruption if the unusable pack is transmitted to the back end, e.g. RS correction to be proceeded can be waived.

If the determined data error type does not belong to predefined reference data error types, the corresponding data stream will be further preceded for DVD playback (step S280). For example, in video stream, if errors occur in B frame data or P frame data, such kind of errors will normally not cause player system crash, nor impose much impacts on playback effect, and they can be corrected during decoding process, therefore, these data can be used for DVD playback.

In above optical disc playback methods, after RS correction and before decoding correction, one more error correction process provided by the present invention is added for the data read from an optical disc. The error correction process utilizes the error detection information obtained by RS verification to perform error correction on data at data stream layer, which will considerably improve the effect of optical disc playback.

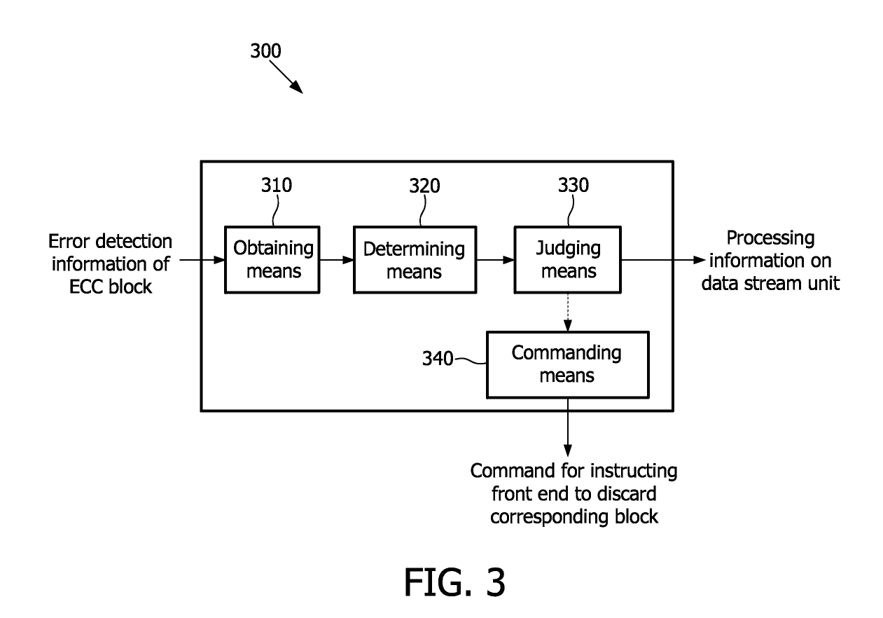

FIG. 3 is a block diagram illustrating an error correction apparatus 300 according to an embodiment of the present invention. The error correction apparatus 300 for DVD will be taken as an example. Error correction apparatus 300 includes an obtaining means 310, which is used to obtain the error detection information as results of verification performed on ECC block by DVD player. According to DVD standard, the front end of DVD player uses RS algorithm to perform error detection and finite error correction on ECC block to determine the address of erroneous data and the amount of errors, etc. For the ECC block with errors under acceptable threshold, obtaining means 310 will obtain the error detection information of the corresponding ECC block.

Error correcting apparatus 300 further includes a determining means 320 for determining the data error type in data stream unit obtained by ECC block, according to the error detection information obtained by obtaining means 310. For example, for a navigation pack obtained from an ECC block, the specific data should be saved in specific address according to DVD standard. If what is saved in the specific address is key information, e.g. link address information or DSI (data search information), and the information encounters severe errors or is not compliant with specified data format, the data and its corresponding information will be determined as non-recovered error, or, in a data stream unit, whether the errors in the data stream unit or the amount of errors in a certain data sector in the data stream unit exceeds an acceptable threshold.

Error correction apparatus 300 further includes a judging means 330, for judging whether to reserve corresponding data stream according to the determined data error type and predefined reference error type. Predefined reference error type could cover the “to be discarded” error types. For example, in a data stream unit, if the amount of errors exceeds predefined criteria, and/or key data encounters non-recovered error, the corresponding data stream unit will be discarded.

Error correction apparatus 300 further includes a instructing means 340, for sending discard command to discard the data relating to the discarded data stream unit. For example, if a navigation pack is discarded, a command should be sent to discard the video pack, audio pack corresponding to the navigation pack or the ECC block which contains these packs. Another example is if one I frame is discarded, the corresponding B frame and P frame which refers to the I frame will be discarded accordingly, and also the group of pictures (GOP) containing the I frame will be discarded as well.

Error correction apparatus 300 could be equipped in an optical disc player for constructing an optical player according to the present invention, so as to enhance error-correction performance and improve playback effect. By using the error correction apparatus provided by the present invention, optical player performs one more error correction to try to eliminate errors which may cause interruption, which improves the playback effect.

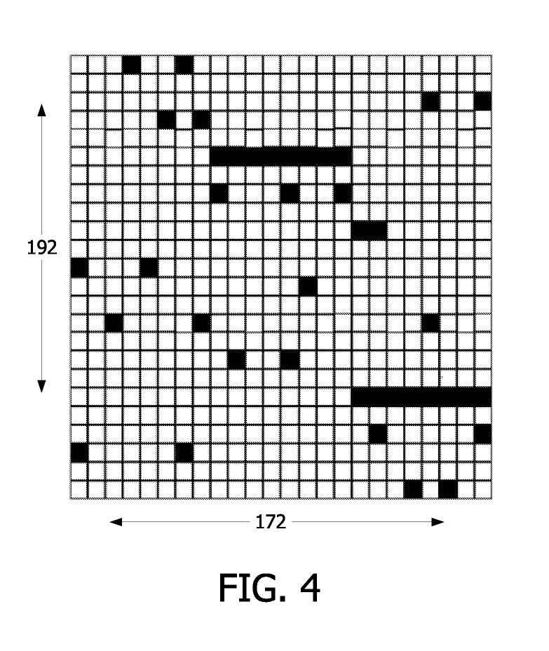

FIG. 4 is a schematic diagram illustrating obtained error detection information corresponding to an ECC block according to an embodiment of the present invention. This figure only illustrates part of error detection information, which manifests the error detection information array (192×172) of 192×172 data array corresponding to one ECC block, wherein, one black square denotes the data error detected by RS algorithm.

The RS error detection performed by the front end of optical disc player is used for ECC block. The error detection information obtained by RS error detection contains the address and the amount of erroneous data in ECC block, shown in FIG. 4. This error detection information can be added to ECC block and transmitted to the back end according to the data structure of ECC block. At the back end of player, according to address information of erroneous data determined by error detection information, the error type can be confirmed.

When the error detection information is transmitted to back end, only 16 error detection information packs are needed to be transmitted for one ECC block with 16-row data, and there is no need to transmit all the detection information to back end. The error detection pack is a structure comprising 12 integers each of which is 16-bit, which can be defined in the following manner:
struct {
UInt16 RowUncor;
UInt16 ColUncor[11];
}DVDUncor;

Wherein, RowUncor is a 16 bit integer variant which indicates the row where uncorrectable errors occur, ColUncor[1] is 11 variants in the form of 16 bit integer, each of which indicates the column where uncorrectable errors occur. The integers which indicate the row and the column respectively can show the location of erroneous data. According to the error detection information pack transmitted to the back end, error detection information can be rebuilt at the back end.

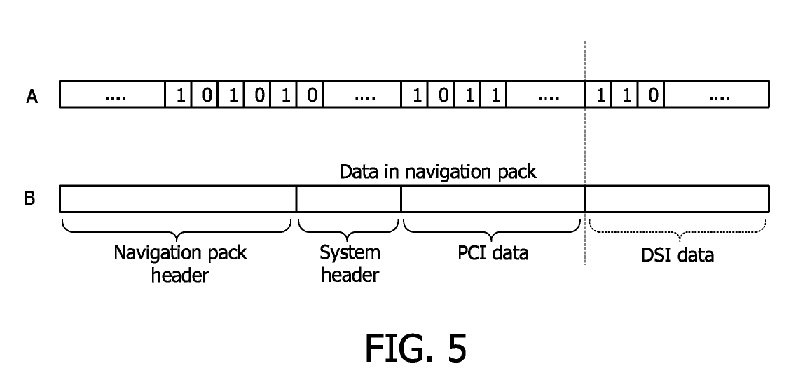

FIG. 5 is a schematic diagram illustrating the determined data error type according to an embodiment of the present invention. Taking navigation pack of DVD as an example, as shown in FIG. 5, row A shows the error detection information, wherein “1” means data error occurring at the address while “0” means OK. Row B shows the data in one navigation pack. According to optical disc specification, the navigation pack includes navigation pack header (14 bytes), system header (24 bytes), PCI (presentation control information) sub-pack (986 bytes) and DSI (data search information) sub-pack (1024 byte). Navigation pack is data with fixed length and specific address saves the data with specific format to represent specific information.

If some bytes in navigation pack header are marked as “1”, it means the header in the navigation pack encounters errors. In conjunction with the DVD standard on specific data in specific byte, the type of erroneous bytes can be determined whether they are navigation pack start code, or system clock reference (SCR), or other information, thereby it can be judged how the occurring errors impact on the navigation pack. If the occurring errors cause the navigation pack unusable, the navigation pack will be discarded.

If errors burst in a certain sector so that the whole data sector can not be restored, the data stream unit is therefore unavailable. For such case, the following method can be used to judge whether the occurring error belongs to the specific error type. We still use navigation pack header as example. Equation (1) is used to determine the error type of navigation pack header:

$${error\_flag}_{t} = {{⋃}_{i = K}}^{N} {Bit}_{i} \qquad ( 1 )$$

Where ∪ means “OR” and t represents different data headers, N means the last byte of the header. Bitᵢ is the I-th bit in error map corresponding to the data headers. K is the sequence number of the start byte in the error map of the header.

SCR base in navigation pack header consists of 6 bytes, which corresponds to 6 bits (Bit₉=0, Bit₈=1, Bit₇=0, Bit₆=1, Bit₅=0, Bit₄=1) in the error map, then the following equation (2) can be obtained from (1):

$${error\_flag}_{nv \_ pack \_ start \_ code} = {{⋃}_{i = 4}}^{7} {Bit}_{i} = 1 \qquad ( 2 )$$

The outcome is 1, which means errors exist in SCR base in navigation pack, and it should be discarded, otherwise the error will probably cause interruption during playback.

Normally speaking, there are two scenarios for video pack: if navigation pack is discarded, the video pack navigated by the navigation pack will be discarded; if one reference frame (e.g. I frame) in video pack is discarded, the data referring to the frame will be discarded too.

Following takes error correction for DVD video pack as an example to describe the error correction method provided by the present invention. According to DVD standard, VOBU (video object unit) is the minimal unit of DVD playback, which normally contains one or more GOPs (Group of Picture). Video pack is navigated by navigation pack for playback.

First is to determine the quantity of whole I frame in a GOP. According to DSI (data search information) in the navigation pack, the end address of first reference frame in a GOP can be yielded. By the following equation 3 the quantity of the reference data packs in the GOP can be calculated.

T_{I}_{_{—}}_{PACK}=VOBU_{—}1STREE_{—}EA−T_{I}_{_{—}}_{NV}_{_{—}}_{PCK}−T_{I}_{_{—}}_{A}_{_{—}}_{PCK}−T_{I}_{_{—}}ₒₜₕₑᵣₛ (3)

Wherein, T_{I}_{_{—}}_{PACK} is the quantity of data stream unit in reference frame pack of GOP;

VOBU_{—}1STREE_EA is the end address of first reference frame in VOBU;

T_{I}_{_{—}}_{NV}_{_{—}}_{PCK} is a navigation pack in a VOBU, and normal value is 1;

T_{I}_{_{—}}_{A}_{_{—}}_{PCK} is the quantity of the audio pack before the end address of first reference picture in a VOBU;

T_{I}_{_{—}}ₒₜₕₑᵣₛ is the quantity of other packs before the end address of first reference picture in the VOBU, like sub-picture etc.

Then, according to the error-detection information corresponding to the ECC block, we can yield the quantity of erroneous I frame contained in a GOP T_{I}_{_{—}}_{PACK}_{_{—}}_{E}. And then, the error rate of I frame in a GOP can be calculated out. If the error rate exceeds a threshold, the GOP is not acceptable and will be discarded.

Although the present invention is described in detail in conjunction with embodiments, it is obvious that those skilled in the art can make various replacements, modifications and changes according to above descriptions. Therefore, all the replacements, modifications and changes should fall in the scope of the invention as defined by the appended claims.

1. An error correction method for correcting errors in data read from a disc, comprising the steps of:
obtaining (120) error detection information of a block corresponding to the read data;
determining (140) data error type in a data stream unit derived from the block, according to the error detection information;
judging (160) whether to reserve the data stream unit for the optical disc playback according to the data error type and predefined reference error type.

2. The method according to claim 1, wherein the block comprises error correction code block (ECC block).

3. The method according to claim 1, wherein the data stream unit comprises navigation pack.

4. The method according to claim 3, further comprising the steps of:
instructing (270) to discard data navigated by the navigation pack, if the navigation pack is not to be reserved.

5. The method according to claim 1, wherein the data stream unit comprises I frame data.

6. The method according to claim 5, further comprising:
instructing (270) to discard B frame(s) and P frame(s) referring to the I frame, if the I frame is to be discarded.

7. The method according to claim 1, wherein the predefined reference error type comprises: an error type indicating whether the quantity of errors in the data stream unit exceeds a predetermined threshold.

8. An error correcting apparatus, for performing error correction on data read from an optical disc, comprising:
an obtaining means (310) for obtaining error detection information of a block corresponding to the read data;
a determining means (320) for determining data error type in a data stream unit derived from the block, according to the error detection information;
a judging means (330) for judging whether to reserve the data stream unit for optical disc playback according to the data error type and predefined reference error type.

9. The apparatus according to claim 8, wherein the block comprises error correction code (ECC) block.

10. The apparatus according to claim 8, wherein the data stream unit comprises navigation pack.

11. The apparatus according to claim 10, further comprising:
an instructing means (340), for instructing to discard data navigated by the navigation pack if the navigation pack is not to be reserved.

12. The apparatus according to claim 8, wherein the data stream unit comprises I frame.

13. The apparatus according to claim 12, further comprising:
a instructing means for instructing to discard B frame and P frame referring to the I frame if the I frame is not to be reserved.

14. The apparatus according to claim 8, wherein the predefined reference error type comprises an error type indicating whether error occurs on specific data.

15. The apparatus according to claim 8, wherein the predefined reference error type comprises an error type indicating whether the quantity of errors in the data stream unit exceeds a predetermined threshold.

16. An optical disc playback method, comprising,
performing (220) error detection for data read from an optical disc;
obtaining (230) error detection information corresponding to a block of the read data;
determining (250) data error type in a data stream unit derived from the block according to the error detection information;
judging (260) whether to reserve the data stream unit for the optical disc playback according to the data error type and predefined reference error type.

17. The method according to claim 16, wherein the block comprises error correction code (ECC) block.

18. The method according to 16, wherein the data stream unit comprises navigation pack.

19. The method according to claim 16, wherein the data stream unit comprises I frame.

20. The method according to claim 16, wherein the predefined reference error type comprises an error type indicating whether error occurs on specific data.

21. The method according to claim 16, wherein the predefined reference error type comprises an error type indicting whether the quantity of errors in the data stream unit exceeds a predetermined threshold.

22. An optical disc player, comprising
a detecting means for performing error detection for data read from an optical disc;
an obtaining means (310) for obtaining error detection information corresponding to a block of the read data;
a determining means (320), for determining data error type in a data stream unit derived from the block, according to the error detection information;
a judging means (330), for judging whether to reserve the data stream unit for playing optical disc according to the data error type and predefined reference error type.

23. The play apparatus according to claim 22, wherein the block comprises error correction code (ECC) Block.
